(19) United States
(12) Patent Application Publication
(10) Pub. No.: US 2010/0123248 A1
(43) Pub. Date: May 20, 2010

(54) SEMICONDUCTOR DEVICE AND METHOD FOR MANUFACTURING THE SAME

(75) Inventor: Masaru YAJIMA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/615,293

(22) Filed: Nov. 10, 2009

(30) Foreign Application Priority Data
Nov. 14, 2008 (JP) 2008-292463
Sep. 25, 2009 (JP) 2009-220797

(51) Int. Cl. H01L 23/48; H01L 21/768

(52) U.S. Cl. 257/741; 438/677; 257/E23.01; 257/E21.575

(57) ABSTRACT

A semiconductor device includes: an electrode pad; a wiring line electrically coupled to the electrode pad, the wiring line being formed by disposing and drying a droplet of a conductive ink in which metal fine particles are dispersed in a dispersion medium; an intermediate layer of an bonded layer of the metal fine particles on a surface of the electrode pad; and a liquid repellent layer that includes a liquid repellent material repelling the dispersion medium and is layered on the intermediate layer to cover the intermediate layer. In the device, the wiring line is physically coupled to the electrode pad with the liquid repellent layer and the intermediate layer interposed between the wiring line and the electrode pad.

### BACKGROUND

1. Technical Field

The present invention relates to a semiconductor device including a wiring line formed by an inkjet method, and a method for manufacturing the same.

2. Related Art

In semiconductor devices including a mounting substrate on which semiconductor components and the like are mounted, there are many cases in which what is called an inkjet method is used as a method for forming wiring lines between electrode pads of the mounting substrate and the electrode pads of the semiconductor components. In the inkjet method, a conductive ink including conductive fine particles dispersed therein is discharged as fine droplets and the droplets are dried. The inkjet method can drastically increase the degree of structural freedom of wiring lines as compared with a conventional wire bonding method because the shape of the wiring line can be changed in unit of droplet. In addition, wiring in the air, which is provided in the wire bonding method, is not required, enabling space occupied by the wiring lines to be reduced. As a result, the semiconductor devices can be downsized.

Incidentally, an inorganic insulation film such as SiO₂ and SiN is formed on an active face and the like of the semiconductor component. Wiring lines drawn by the inkjet method on such insulation film, which serves as an underlayer, show poor reliability because the wiring lines hardly keep good adhesiveness with the underlayer, may be peeled off from the underlayer to cause disconnection, and have insufficient mechanical strength due to poor integrity with the underlayer. In a case where wiring lines are formed by the inkjet method, a face on which the wiring lines are formed needs to be made uniform at an appropriate state so that droplets disposed on the face can uniformly wet and spread, which can prevent disconnection due to an insufficient spreading of the droplets or an electrical short due to an excess spreading of the droplets from occurring, for example.

In order to cope with the above problem, JPA-2006-147650 discloses a semiconductor device, in which an organic insulation film is formed on an active face including electrode pads of a semiconductor component. The organic insulation film shows a satisfactory bonding force and adhesiveness with respect to the wiring lines formed by the inkjet method. As a result, the wiring lines formed by the inkjet method are adhesively bonded to the organic insulation film serving as the underlayer with an appropriate bonding force and adhesiveness. The organic insulation film also can make the active face uniform to an appropriate state, also making it possible to maintain the wetting and spreading of the droplets disposed on the active face at an appropriate state. As a result, reliability of the wiring lines drawn by the inkjet method can be improved.

Recently, with the miniaturization of the semiconductor devices, fine wiring patterns also have been strongly demanded. Particularly, in a case where fine wiring patterns are drawn on the semiconductor components or the mounting substrate by the inkjet method, it is preferable that droplets that are discharged and disposed be kept at a drawing face while maintaining a predetermined size because if the droplets discharged and disposed widely wet and spread on the drawing face, it becomes difficult that fine patterns are drawn by the droplets discharged and disposed. Therefore, a surface treatment is conducted to form, on the drawing face on which the droplets are disposed, a liquid repellent layer including a liquid repellent material showing liquid repellency with respect to the droplet so that the liquid repellent layer can hold the droplets on the drawing face with a predetermined size. The surface treatment suppresses the droplets disposed on the drawing face from wetting and spreading, allowing a desired fine pattern to be drawn on the drawing face with the droplets disposed by the inkjet method, and thereafter the pattern is dried and fired. As a result, a fine wiring pattern can be formed.

Here, many semiconductor components and the mounting substrates have the electrode pads to mutually connect circuits. If the liquid repellent layer is formed also on the electrode pads by the surface treatment, the electrical connection between the wiring lines formed by drying and firing the droplets and the electrode pads may not be secured since the liquid repellent layer is sandwiched between the droplets forming the wiring lines and the electrode pads. For example, the liquid repellent layer is uniformly and stably formed on the electrode pad on which gold is plated to prevent the pad surface from being oxidized since the surface is smooth. Because of this, even a wiring line is formed by the droplets disposed on such liquid repellent layer, the electrical connection between the wiring line and the electrode pad may be highly hindered. Even if the electrical connection is temporarily secured, the bonding force between the wiring line and the electrode pad becomes weak since the liquid repellent layer is interposed therebetween, which may cause connection failures.

### SUMMARY

An advantage of the invention is to provide a semiconductor device that can appropriately secure an electrical connection between an electrode pad of a semiconductor component provided in the semiconductor device and a wiring line formed by an inkjet method so as to be connected to the electrode pad, and a method for manufacturing the semiconductor device.

According to a first aspect of the invention, a semiconductor device includes an electrode pad; a wiring line electrically coupled to the electrode pad, the wiring line being formed by disposing and drying a droplet of a conductive ink in which metal fine particles are dispersed in a dispersion medium; an intermediate layer of an bonded layer of the metal fine particles on a surface of the electrode pad; and a liquid repellent layer that includes a liquid repellent material repelling the dispersion medium and is layered on the intermediate layer to cover the intermediate layer. In the device, the wiring line is physically coupled to the electrode pad with the liquid repellent layer and the intermediate layer interposed between the wiring line and the electrode pad.

If an underlayer has a uniform plane, the liquid repellent layer is stably and uniformly formed along the underlayer. It may occur that the conduction between the wiring line formed on the liquid repellent layer and the electrode pad serving as the underlayer is hindered by the liquid repellent layer.

In order to avoid such occurrence, the intermediate layer made of the bonded metal fine particles is formed in the electrode pad, and then the droplets disposed on the intermediate layer with the liquid repellent layer interposed therebetween are fired so as to form the wiring line made of the metal fine particles. This results in ridges and valleys (roughness) corresponding to the sizes of bonded metal fine particles being formed on the surface of the intermediate layer. The liquid repellent layer is, thus, unevenly formed so as to cover the surface in plane view, whereby the metal particles protrude in spots of the liquid repellent layer. Accordingly, in the case where the metal fine particles of the wiring line are disposed on the intermediate layer with the liquid repellent layer sandwiched therebetween, the metal fine particles, which protrude in spots of the liquid repellent layer, of the intermediate layer and the metal fine particles of the wiring line are made contact with each other. As a result, a physical connection between the intermediate layer and the wiring line are secured. The electrical connection is also secured.

In the device, the intermediate layer and the wiring line may be made of metal of a same kind.

In the semiconductor device, the intermediate layer and the wiring line are made of the same kind of metal. The intermediate layer and the wiring line are strongly bonded by the coagulation, and a stronger fusing force is easily obtained as compared with the junction or bonding between metals of different kinds. As a result, the intermediate layer and the wiring line are firmly connected and the electrical connection between them is more stably achieved though the liquid repellent layer is sandwiched therebetween.

In the device, the surface of the electrode pad may be plated with gold; and the intermediate layer may be formed on the surface plated with gold.

According to the structure, since the surface of the electrode pad is covered with gold, the surface of the pad is hardly oxidized. The conduction between the intermediate layer formed on the surface and the electrode pad is, thus, appropriately secured. Incidentally, if the intermediate layer is formed by an inkjet method and an oxide film is formed on the electrode pad, it is preferable that the droplets of a conductive ink be disposed after removing the oxide film. However, no oxide film is formed. Thus, the intermediate layer is easily formed by the inkjet method.

In a case where silver is used as metal for the metal fine particles, the electrical connection between the intermediate layer and the electrode pad is appropriately secured since silver is bonded with gold stronger than, for example, aluminum.

In the device, the liquid repellent layer may be a single molecule film of the liquid repellent material.

According to the structure, the liquid repellent layer is formed on an area excluding the intermediate layer as a single molecule film showing desired liquid repellency. The liquid repellent layer is disposed on the intermediate layer having ridges and valleys as single molecule since it is single molecule film. As a result, the single molecule is unevenly disposed and the metal fine particles protrude in spots of the liquid repellent layer. Accordingly, the metal fine particles of the intermediate layer and the metal fine particles of the wiring line are appropriately made contact with each other while the single molecule film is sandwiched between the intermediate layer and the wiring line, and thereafter they are bonded with a strong fusing force by being dried and fired. As a result, the stability of the electrical connection between the electrode pad and the wiring line is further improved.

In the device, the liquid repellent material may be a fluorine material.

According to the structure, since high liquid repellency with respect to the dispersion medium is given to the liquid repellent material, it is suppressed that the droplets disposed by the inkjet method wet and spread. As a result, the inkjet method allows fine wiring patterns to be drawn to the semiconductor device.

In the device, the electrode pad may be an electrode that is provided on an active face of a semiconductor component as a connecting terminal to an external circuit, and has a pad-like shape.

According to the structure, wiring lines can be drawn to the connecting terminals for external devices of the semiconductor components of the semiconductor device by the inkjet method, enabling the application of the semiconductor device including the semiconductor components to be expanded.

A second aspect of the invention is a method for manufacturing a semiconductor device in which a wiring line electrically coupling to an electrode pad of the semiconductor device is formed by disposing and drying a droplet of a conductive ink in which metal fine particles are dispersed in a dispersion medium. The method includes forming, on a surface of the electrode pad, an intermediate layer of a bonded layer of the metal fine particles; layering a liquid repellent layer including a liquid repellent material repelling the dispersion medium to cover the intermediate layer after forming the intermediate layer; and forming the wiring line on the electrode pad with the liquid repellent layer and the intermediate layer that have been layered interposed between the wiring line and the electrode pad.

If an underlayer has a uniform plane, the liquid repellent layer is stably and uniformly formed along the underlayer. It may occur that the conduction between the wiring line formed on the liquid repellent layer and the electrode pad serving as the underlayer is hindered by the liquid repellent layer.

In order to avoid such occurrence, the intermediate layer made of the bonded metal fine particles is formed in the electrode pad, and then the droplets disposed on the intermediate layer with the liquid repellent layer interposed therebetween are fired so as to form the wiring line made of the metal fine particles. This results in ridges and valleys (roughness) corresponding to the sizes of bonded metal fine particles being formed on the surface of the intermediate layer. The liquid repellent layer is, thus, unevenly formed so as to cover the surface in plane view, whereby the metal particles protrude in spots of the liquid repellent layer. Accordingly, in the case where the metal fine particles of the wiring line are disposed on the intermediate layer with the liquid repellent layer sandwiched therebetween, the metal fine particles, which protrude in spots of the liquid repellent layer, of the intermediate layer and the metal fine particles of the wiring line are made contact with each other. As a result, a physical connection between the intermediate layer and the wiring line are secured. The electrical connection is also secured.

In the method, the intermediate layer and the wiring line may be made of metal of a same kind.

According to the method, the intermediate layer and the wiring line are made of the same kind of metal. The intermediate layer and the wiring line are, thus, strongly bonded by the coagulation, and a stronger fusing force is easily obtained as compared with the junction or bonding between metals of different kinds. As a result, the intermediate layer and the wiring line are firmly connected and the electrical connection between them is more stably achieved though the liquid repellent layer is sandwiched therebetween.

In the method, the surface of the electrode pad may be plated with gold; and the intermediate layer may be formed on the surface plated with gold.

According to the method, since the surface of the electrode pad is covered with gold, the surface of the pad is hardly oxidized. The conduction between the intermediate layer formed on the surface and the electrode pad is, thus, appropriately secured. Incidentally, if the intermediate layer is formed by an inkjet method and an oxide film is formed on the electrode pad, it is preferable that the droplets of a conductive ink be disposed after removing the oxide film. However, no oxide film is formed. Thus, the intermediate layer is easily formed by the inkjet method.

In a case where silver is used as metal for the metal fine particles, the electrical connection between the intermediate layer and the electrode pad is appropriately secured since silver is bonded with gold stronger than, for example, aluminum.

In the method, the liquid repellent layer may be a single molecule film of the liquid repellent material.

According to the method, the liquid repellent layer is formed on an area excluding the intermediate layer as a single molecule film showing desired liquid repellency. The liquid repellent layer is disposed on the intermediate layer having ridges and valleys as single molecule since it is the single molecule film. As a result, the single molecule is unevenly disposed and the metal fine particles protrude in spots of the liquid repellent layer. Accordingly, the metal fine particles of the intermediate layer and the metal fine particles of the wiring line are appropriately made contact with each other while the single molecule film is sandwiched between the intermediate layer and the wiring line, and thereafter they are bonded with a strong fusing force by being dried and fired. As a result, the stability of the electrical connection between the electrode pad and the wiring line is further improved.

In the method, the droplet of the conductive ink may be disposed on the electrode pad and fired to form the intermediate layer.

According to the method, the intermediate layer is formed by disposing the droplets of the conductive ink on the electrode pad with the inkjet method. Ridges and valleys (roughness) corresponding to the sizes of fine particles are easily formed on the surface of the intermediate layer formed by the inkjet method. In addition, in a case where the electrode pad is plated with gold, it is not required to remove films, such as oxide films formed on the electrode pad, which serve as factors hindering electrical conduction before the intermediate layer is formed.

In the method, the liquid repellent material may be a fluorine material.

According to the method, since high liquid repellency with respect to the dispersion medium is given to the liquid repellent material, it is suppressed that the droplets disposed by the inkjet method wet and spread. As a result, the inkjet method allows fine wiring patterns to be drawn to the semiconductor device.

### BRIEF DESCRIPTION OF THE DRAWINGS

The invention will be described with reference to the accompanying drawings, wherein like numbers reference like elements.

FIGS. 1A and 1B show an embodiment of a semiconductor device according to the invention. FIG. 1A shows a planar structure viewed from the top side while FIG. 1B shows a sectional structure of a part along the line 1b-1b shown in FIG. 1A.

FIG. 2 shows the embodiment of the semiconductor device of the invention, and an enlarged partial sectional view showing a part of FIG. 1B.

FIG. 3 is a flow chart showing steps to form wiring lines on the semiconductor device.

FIGS. 4A through 4E are sectional views showing a manufacturing state of each step.

### DESCRIPTION OF EXEMPLARY EMBODIMENTS

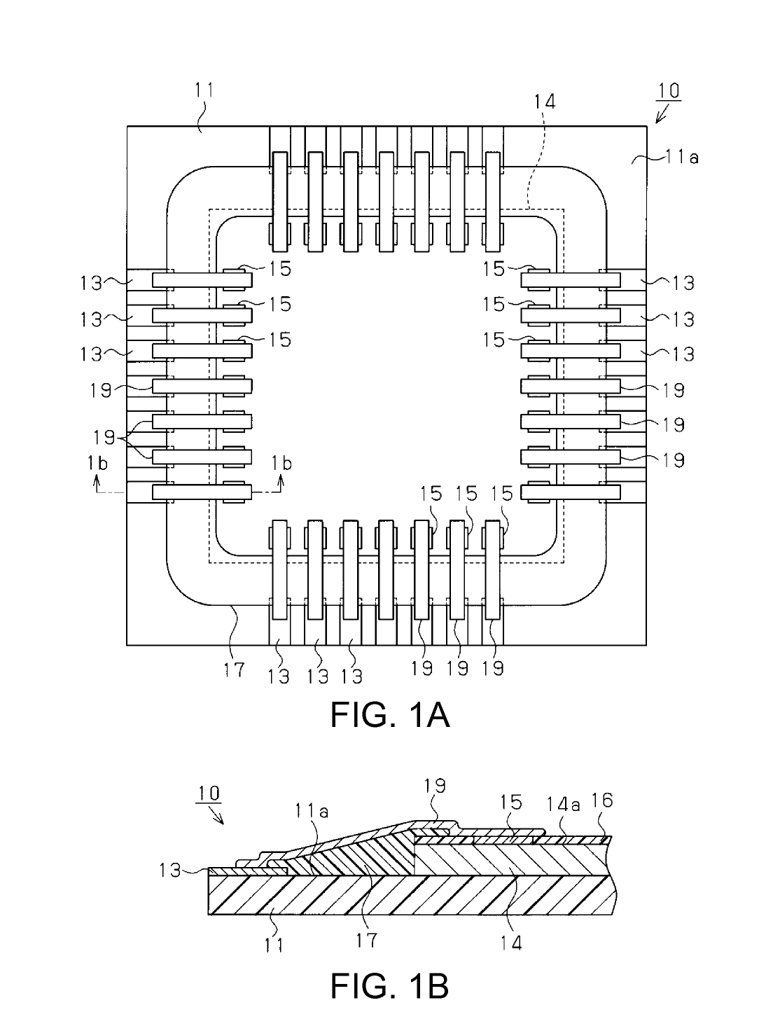

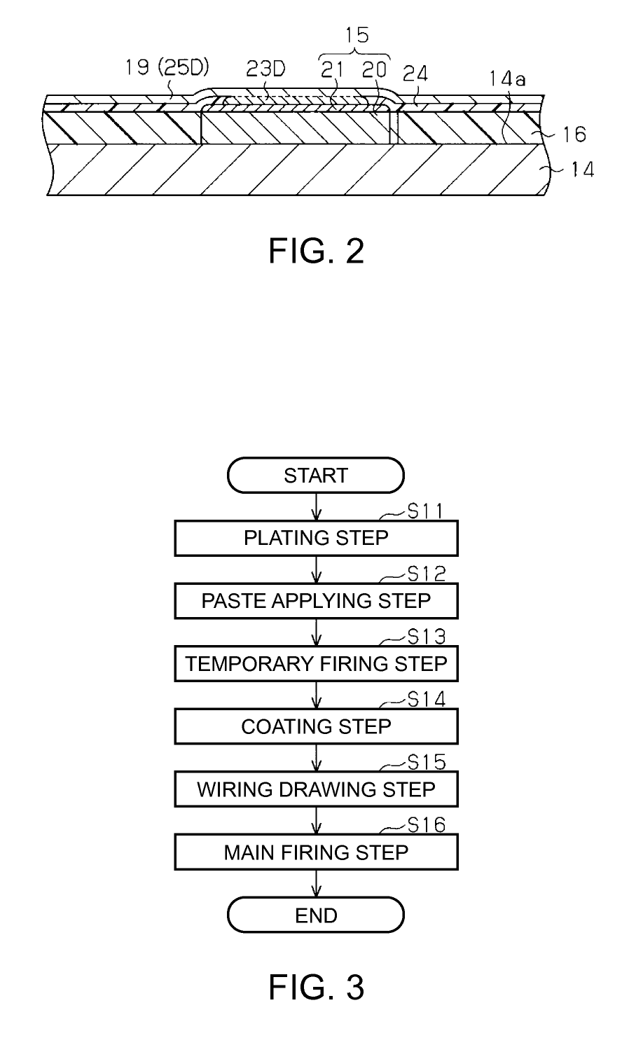

An embodiment of a semiconductor device according to the invention will be described below with reference to FIGS. 1A, 1B and FIG. 2. FIGS. 1A and 1B show a semiconductor device 10. FIG. 1A shows a planar structure viewed from the top side while FIG. 1B shows a sectional structure of a part along the line 1b-1b shown in FIG. 1A. FIG. 2 is an enlarged view of a part of the sectional structure along the line 1b-1b shown in FIG. 1B.

As shown in FIGS. 1A and 1B, a mounting substrate 11 included in the semiconductor device 10 is a multilayer substrate having a rectangular shape when viewed from an up-down direction, which is a direction along the thickness. On the top layer of the mounting substrate 11, an insulation substrate (not shown) having an insulation property is layered. On the top surface of the insulation substrate, i.e., a mounting surface 11a serving as the top surface of the mounting substrate 11, first electrode pads 13 having a rectangular shape when viewed from an above direction are arranged along four sides of the mounting surface 11a.

The insulation substrate (the top layer of the mounting substrate 11) can be made of flexible or non-flexible various insulation materials. Examples of such flexible materials include synthetic resin such as polyimide resin, epoxy resin, polyester resin, phenol resin, and fluorine resin. Further, examples of such non-flexible materials include a high temperature fired base material and a dielectric material in addition to glass ceramic, which is a low temperature fired base material.

In this regard, the mounting substrate 11 may have various kinds of wiring lines on the mounting surface 11a in addition to the first electrode pads 13. The mounting substrate 11 also may be a multilayer substrate having a plurality of circuit boards on which various kinds of wiring lines are printed as long as the first electrode pads 13 are formed on the mounting surface 11a. Further, in the mounting substrate 11, the first electrode pads 13 may be formed along only one side of the mounting surface 11a, for example, though they are arranged in the four sides of the mounting surface 11a in the embodiment.

On the mounting surface 11a, bonded is a semiconductor chip 14 serving as a semiconductor component with an adhesive layer (not shown) interposed therebetween so as to be surrounded by the first electrode pads 13. The semiconductor chip 14 has a rectangular plate-like shape when viewed form the above direction. The semiconductor chip 14 has a pad forming face 14a serving as the top surface, on which a plurality of second electrode pads 15 each having a rectangular shape when viewed from the above direction and serving as a connection terminal is arranged along the four sides of the semiconductor chip 14 in a manner such that each second electrode pad 15 corresponds to one of the first electrode pads 13 of the mounting substrate 11.

As shown in FIG. 2, the second electrode pad 15 is composed of a main body 20 and a plated layer 21. The main body 20 is made of aluminum, which is metal having conductivity. The plated layer 21 is formed on the top surface of the main body 20 by a gold plaiting. The plated layer 21 is uniformly formed along the main body 20 by an electrolytic plating or a nonelectrolytic plating of gold after removing an oxide film of aluminum formed on the top surface of the main body 20. Accordingly, the second electrode pad 15 has the plated layer 21 that is formed on the top face and hardly oxidized. The plated layer 21 enables electrical contact with a wiring line formed on it by an inkjet method in later step to be secured without being hindered by an oxide film formed on it.

The semiconductor component may be not only an active component such as the semiconductor chip 14 but also a passive component such as resistors and capacitors as long as it can be mounted by what is called a face-up method. The face-up method is exemplified as a case where the semiconductor chip 14 is mounted to the mounting surface 11a in a manner such that a side opposite to the pad forming face 14a, on which the second electrode pads 15 are formed, faces the mounting surface 11a. While the second electrode pads 15 are arranged along the four sides of the pad forming face 14a of the semiconductor chip 14, the second electrode pads 15 are formed along only one side of the pad forming face 14a or only one of the second electrode pads 15 may be formed, for example, in the same manner of the first electrode pads 13 of the mounting substrate 11.

The second electrode pad 15 has an intermediate layer 23D layered on the plated layer 21. The intermediate later 23D is a bonded layer of metal fine particles formed by what is called an inkjet method, and formed by the following manner: droplets of a conductive ink that are discharged and disposed are dried and fired, so that metal fine particles included in the conductive ink are sintered. In the embodiment, the conductive ink includes a silver nano paste, which having a particle diameter of from 1 nanometer (nm) to several tens of nanometers. Particularly, the ink shows a colloidal state, in which outer surfaces of silver fine particles, serving as metal fine particles, having a diameter of from 1 to 5 nm are coated with a dispersant, and diluted with a dispersion medium (water, in the embodiment). That is, the silver nano paste are prevented from being coagulated and bonded each other so as to be dispersed in the dispersion medium since the outer surfaces of the silver fine particles are coated with the dispersant.

Examples of the metal fine particles can include ones of silver, gold, copper, mixtures thereof, and alloys thereof. Examples of the dispersant (coating agent) of the metal fine particles include amine, alcohol, and thiol. Specifically, as the coating agent of the metal fine particles, an amine compound such as 2-methylaminoethanol, diethanolamine, diethylmethylamine, 2-dimethylaminoethanol, and methyldiethanolamine, alkylamines, ethylendiamine, alkylalchols, ethylene glycol, propylene glycol, alkylethiols, or ethanedithiol can be used.

Any dispersion medium can be used as long as it is capable of dispersing the metal fine particules and does not cause coagulation. Examples of the medium can include: water; alcohols such as methanol, ethanol, propanol, and butanol; hydro-carbon compounds such as n-heptane, n-octane, decane, dodecane, tetradecane, toluene, xylene, cymene, durene, indene, dipentene, tetrahydronaphthalene, decahydronaphthalene, and cyclohexylbenzene; ether compounds such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis(2-methoxyethyl) ether, and p-dioxane; and polar compounds such as propylene carbonate, gamma-butyrolactone, N-methyl-2-pyrrolidone, dimethylformamide, dimethyl sulfoxide, and cyclohexanone. Water, alcohols, the carbon hydride compounds, and the ether compounds are preferable for the dispersion medium, water and the carbon hydride compounds are much preferred from the following points of view: a dispersion of the fine particles, stability of dispersion liquid, and an ease of the application for a droplet discharge method (inkjet method).

When the silver nano paste is fired, the dispersant coating the silver fine particles and the dispersion medium in which the silver fine particles are dispersed are decomposed or vapor, resulting in the silver fine particles being directly made contact with each other. As a result, the silver fine particles fuse with each other, being bonded with a predetermined fusing force. In other word, the intermediate layer 23D is formed by sintering the silver fine particles in firing the silver nano paste. Since the intermediate layer 23D is formed by sintering the silver fine particles, some of the outer shapes of the silver fine particles remain on the top surface. As a result, ridges and valleys (roughness) based on the sizes of the silver fine particles are formed on the top surface. The intermediate layer 23D is also preferably, physically and chemically bonded to the plated layer 21 mainly made of gold, which has high affinity with silver constituting the intermediate layer 23D. The intermediate layer 23D is, thus, electrically bonded to the second electrode pad 15 preferably and securely with the plated layer 21 interposed therebetween.

On the pad forming face 14a, formed is an insulation layer 16 so as to expose the second electrode pads 15. The insulation layer 16 is a thin film made of an inorganic insulation material or an organic insulation material. As for the inorganic insulation material, SiO₂, SiN or the like can be used. As for the organic insulation material, polyimide resin or the like can be used. The insulation layer 16 is formed by the inkjet method using an insulating ink containing an insulation material such as the inorganic insulation material and the organic insulation material. The insulation layer 16 has a liquid repellent layer 24 layered on the top surface.

The liquid repellent layer 24 is formed, for example, by a dispenser method in a manner such that a coating agent including a liquid repellent material is spread entirely over an area including the insulation layer 16, the plated layer 21, and the intermediate layer 23D above the pad forming face 14a. This is because that the liquid repellent layer 24 does not need to be formed with high accuracy. The liquid repellent layer 24 is formed as a single molecular film in which molecules included in the liquid repellent material are uniformly arranged so as to form a uniform thin thickness. In the embodiment, fluorine resin, which shows liquid repellency with respect to the dispersion medium of the conductive ink later described, or the like can be used as the liquid repellent material.

Specifically, the liquid repellent material forms a self-assembled film, which is composed of an organic molecular film and the like, on the insulation layer 16, the plated layer 21 and the intermediate layer 23D. The organic molecular film has, at one side, a functional group capable of bonding the surfaces of the insulation layer 16 and the like, at the other side opposite to the functional group bonded to the surface of an underlayer of the organic molecular film, another functional group showing liquid repellency, and a direct carbon chain connecting the functional groups or a partially branched carbon chain. The organic molecular film is bonded to the insulation layer 16 and the like to be self-assembled, forming a molecular film such as a single molecular film.

That is, the self-assembled film is formed by orienting a compound that includes molecules that have bonding functional groups capable of chemically bonding with atoms included in an underlayer such as the insulation layer 16, and a base skeleton of a direct-chain-like shape, and show an extremely high orientation by mutual action among the direct-chain molecules. Since the self-assembled film is formed by orienting single molecule, the film can be formed with an extremely thin thickness and uniformly at a molecular level. In other words, providing functional groups having the same liquid repellency on the film surface can give excellent liquid repellency on the film surface uniformly.

For example, if fluoroalkylsilane is used as the compound having high orientation, each compound is orientated in a manner such that the fluoroalkyl group is oriented on the film surface to form a self-assembled film. As a result, liquid repellency is uniformly given to the film surface.

Examples of the compound forming the self-assembled film include fluoroalkylsilane (hereinafter referred to as “FAS”) such as heptadecafluoro-1,1,2,2-tetrahydrodecyl-triethoxysilane, heptadecafluoro-1,1,2,2-tetrahydrodecyl-trimethoxysilane, heptadecafluoro-1,1,2,2-tetrahydrodecyl-trichlorosilane, tridecafluoro-1,1,2,2-tetrahydrooctyl-triethoxysilane, tridecafluoro-1,1,2,2-tetrahydrooctyl-trimethoxysilane, tridecafluoro-1,1,2,2-tetrahydrooctyl-trichlorosilane, and trifluoropropyl trimethoxysilane. One of these compounds may be used as alone or in combination of two or more of them may be used.

In this way, the liquid repellent layer 24 showing appropriate liquid repellency is formed on the pad forming face 14a with an extremely thin thickness. The liquid repellent layer 24 is formed so as to appropriately cover the top surface of the insulation layer 16, which serves as a uniform underlayer, since the liquid repellent layer 24 is a single molecule film. In contrast, it is hard that the liquid repellent material is uniformly provided on the top surface of the intermediate layer 23D as compared with the insulation layer 16 and the plated layer 21, which also serve as an underlayer. This is because that the top surface of the intermediate layer 23D serving as the underlayer has ridges and valleys (rough surface). As a result, the liquid repellent material is unevenly provided, so that the silver fine particles of the intermediate layer 23D protrude through the thickness direction of the liquid repellent layer 23. On the underlayer surface having a convex curve, the interval between liquid repellent groups serving as the surface of the self-assembled film constituting the liquid repellent layer 23 becomes wider since the self-assembled film is composed of direct-chain-like molecules extending in the normal direction of the convex curve. On the underlayer surface having a concave curve, it is hard that the direct-chain-like molecules are densely provided on the underlayer surface. This is because that the self-assembled film constituting the liquid repellent layer 23 is also composed of the direct-chain-like molecules extending in the normal direction of the concave curve, resulting in mutual action among the direct-chain-like molecules is stronger than that on the plane face. Consequently, the liquid repellent layer 24 on the intermediate layer 23D has liquid repellency, with respect to the droplets of the conductive ink, lower than that on the insulation layer 16 and the plated layer 21 serving as the underlayer while desired wiring lines may be formed.

A step corresponding to the thickness of the semiconductor chip 14 is formed between the mounting surface 11a and the pad forming face 14a. A slope 17 is formed at an outer circumference of the semiconductor chip 14. The slope 17 is a sloped portion having a continuous face connecting the mounting surface 11a and the pad forming face 14a. The continuous face smoothly connects the steps. The slope 17 is formed so as to cover a part of each first electrode pad 13 and a part of the insulation layer 16. The slope 17 is made of an insulation material. As for the insulation material, thermosetting resin such as epoxy resin, light curing resin such as acrylic resin, or a mixture of these can be used.

On a surface of the slope 17, formed are metal wiring films 19 each serving as a wiring line electrically connecting the first electrode pad 13 and the second electrode pad 15. The metal wiring film 19 is formed by the inkjet method using a conductive ink of a metal fine particles dispersion type. In the embodiment, the silver nano paste used to form the intermediate layer 23D is used as the conductive ink to from the metal wiring film 19. That is, in the embodiment, the same kind of metal is used for the intermediate layer 23D and the metal wiring film 19. As for the metal fine particles of the conductive ink used to form the metal wiring film 19, ones of gold, cupper, and alloys thereof in addition to silver can be used in the same manner of the intermediate layer 23D. The dispersant and the dispersion medium aforementioned also can be used as ones for the metal fine particles.

In the embodiment, the intermediate layer 23D is formed on the plated layer 21 of the second electrode pad 15, and the liquid repellent layer 24 is formed on the intermediate layer 23D as shown in FIG. 2. The liquid repellent layer 24 on the intermediate layer 23D, however, has thin-thickness parts as described above, and the silver particles, thus, protrude. Accordingly, the metal wiring film 19 formed on the intermediate layer 23D directly makes contact with the intermediate layer 23D with the protruding silver particles. As a result, the silver fine particles of the metal wiring film 19 and the silver fine particles of the intermediate layer 23D are directly made contact with to be physically and chemically bonded. Then, the silver fine particles are fused to each other in drying and firing to be bonded with a predetermined fusing force. In the processes of drying and firing, the thin-thickness parts of the liquid repellent material forming the liquid repellent layer 24 are arbitrarily moved or dispersed between the intermediate layer 23D and the metal wiring film 19. As a result, the liquid repellent material is appropriately disposed so as not to hinder the bonding of the intermediate layer 23D and the silver fine particles of the metal wiring film 19 even in a region where they are bonded.

Consequently, the metal wiring film 19 is coupled to the plated layer 21 of the second electrode pad 15 with the intermediate layer 23D interposed therebetween, enabling the electrical connection to the second electrode pad 15 (the main body 20) to be secured.

Incidentally, in a case where the first electrode pad 13 and the second electrode pad 15 are connected by wire bonding, the mounting substrate 11 and the semiconductor chip 14 are heated at high temperature, and large mechanical stresses are locally applied to them. Therefore, in the case of wire bonding, heat resistance and durability against mechanical stress is highly demanded for the mounting substrate 11 and the semiconductor chip 14. However, forming the metal wiring film 19 by using a droplet discharge method as shown in the embodiment can reduce the demands for the mounting substrate 11 and the semiconductor chip 14, enabling the degree of freedom of a material selection to be increased.

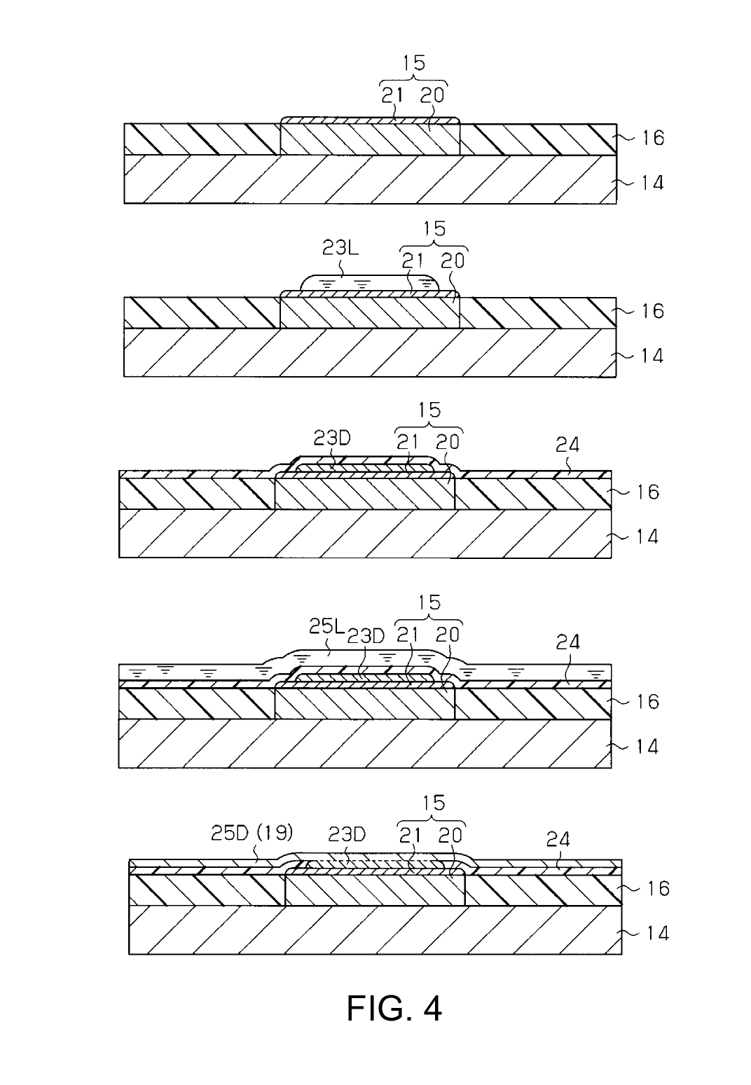

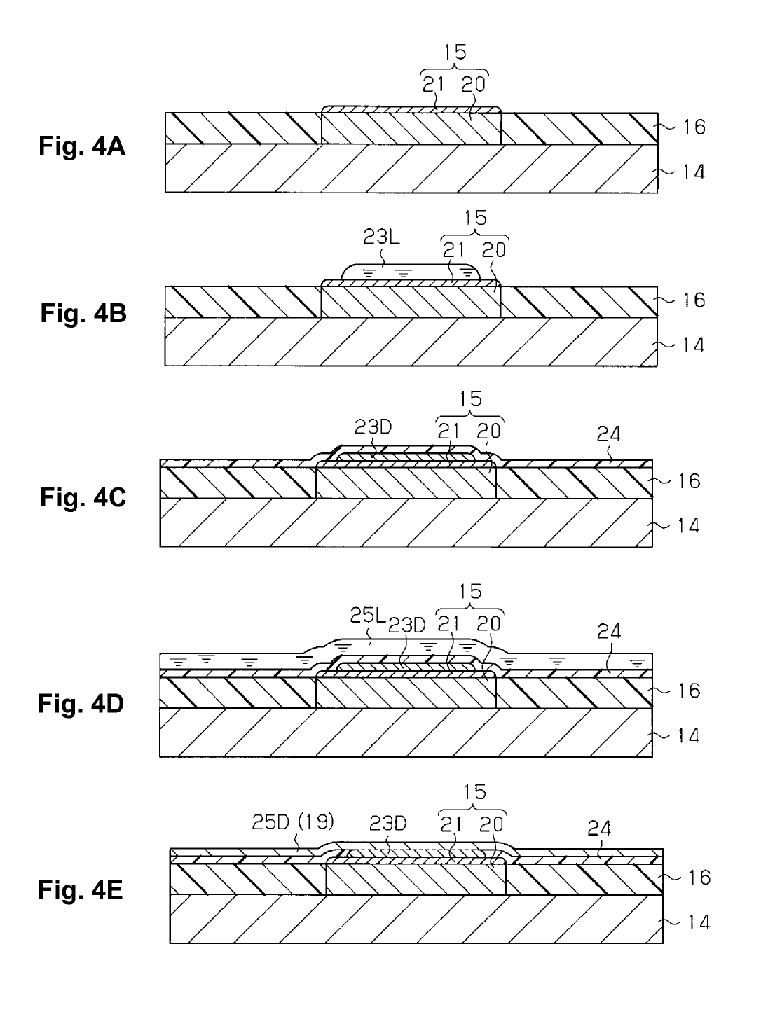

Next, a method for manufacturing the semiconductor device 10 is described. FIG. 3 is a flowchart showing the steps to form wiring lines in the semiconductor device. FIGS. 4A to 4E show the sectional structure of the semiconductor device in each step shown in FIG. 3.

As shown in FIG. 3, the steps to form the wiring lines include a plating step (step S11) to form the plated layer 21 of the second electrode pad 15, a paste applying step (step S12) to dispose droplets including the silver fine particles to the plated layer 21, and a temporary firing step (step S13) to fire the droplets so as to form the intermediate layer 23D made of the silver fine particles. The steps to form the wiring lines also include a coating step (step S14) to form the liquid repellent layer 24 on the intermediate layer 23D, a wiring drawing step (step S15) to dispose on the liquid repellent layer 24 the droplets including the silver fine particles to form the metal wiring film 19, and a main firing step (step S16) to fire the droplets so as to form the metal wiring film 19.

In the plating step, as shown in FIG. 4A, oxide films formed on the top surface of the main body 20, which is made of aluminum, of the second electrode pad 15 are removed, and then gold is plated on the top surface by a non-electrolytic plating or an electrolytic plating to form the plated layer 21.

This step is not required to be continuous in time to a succeeding step since the plated layer 21 is formed on the second electrode pad 15 so as to prevent electrical connection between the second electrode pad 15 and the wiring lines formed in the succeeding step from being hindered by oxide films formed on the second electrode pad 15. The plated layer 21 suppresses the oxidization of the second electrode pad 15. In other words, other steps may be included between the plating step and the step succeeding the plating step.

In the paste applying step, as shown in FIG. 4B, a liquid layer 23L is formed on the plated layer 21 of the second electrode pad 15. The liquid layer 23L is formed with the silver nano paste disposed by the inkjet method.

In the temporary firing step, as shown in FIG. 4C, the liquid layer 23L formed in the paste applying step is fired at 180° C. to 230° C. for about 1 hour. The dispersant coating the silver fine particles and the dispersion medium dispersing the silver fine particles are decomposed and vapor, resulting in the silver fine particles being directly made contact with each other to be coagulated and bonded. As a result, the intermediate layer 23D mainly made of the silver fine particles is formed. That is, the silver fine particles are coagulated and bonded and fixed with a predetermined fusing force by firing the silver nano paste, forming the intermediate layer 23D that is made of the silver fine particles and securely has conductivity. The surface of the fixed intermediate layer 23D has ridges and valleys (roughness) based on the sizes of the silver fine particles.

The intermediate layer 23D is bonded to the second electrode pad 15 with a predetermined bonding force and the electrical connection is appropriately secured by being bonded to the plated layer 21 made of gold having high affinity with the silver fine particles. That is, the intermediate layer 23D secured to have the electrical connection to the second electrode pad 15 is layered on the plated layer 21 of the second electrode pad 15.

In the coating step, as also shown in FIG. 4C, a predetermined amount of droplets of the liquid repellent ink is dropped above the pad forming face 14a of the semiconductor chip 14, i.e., on the top surfaces of the insulation layer 16, the plated layer 21 of the second electrode pad 15 and the intermediate layer 23D by a dispenser method. The droplets spread and are dried to form the liquid repellent layer 24.

In the wiring drawing step, as shown in FIG. 4D, the droplets of the silver nano paste are disposed by the inkjet method on the liquid repellent layer 24 so as to cover an area above the intermediate layer 23D to form a liquid layer 25L of the silver nano paste. The liquid layer 25L is disposed on the liquid repellent layer 24 and the intermediate layer 23D so as to be the same pattern of the metal wiring film 19 since the liquid layer 25L is formed as the metal wiring film 19 in the following step.

In the main firing step, as shown in FIG. 4E, the liquid layer 25L formed in the wiring drawing step is fired at 180° C. to 230° C. for about 1 hour so as to form the wiring layer 25D made of the silver fine particles. In this way, the wiring layer 25D (the metal wiring film 19) is formed that is made of the silver fine particles that are fixed by being bonded with a predetermined fusing force and secured to have the conductivity.

The wiring layer 25D is also bonded to the intermediate layer 23D, of which the silver fine particles protrude in spots of the liquid repellent layer 24, with the silver fine particles included thereof by being coagulated and bonded with a predetermined fusing force. Meanwhile, the liquid repellent material constituting the liquid repellent layer 24 disposed between the wiring layer 25D and the intermediate layer 23D is arbitrarily dispersed and disposed between the silver fine particles constituting the wiring layer 25D and the intermediate layer 23D. As a result, the wiring layer 25D and the intermediate layer 23D are bonded with a predetermined fusing force and the electrical connection is secured though the liquid repellent layer 24 is sandwiched therebetween.

As described above, the following effects can be obtained by the semiconductor device 10 of the embodiment.

(1) If an underlayer has a uniform plane, the liquid repellent layer 24 is stably and uniformly formed along the underlayer. It may occur that the conduction between the metal wiring film 19 formed on the liquid repellent layer 24 and the second electrode pad 15 serving as the underlayer is hindered by the liquid repellent layer 24.

In order to avoid such occurrence, the intermediate layer 23D made of the bonded silver fine particles is formed in the second electrode pad 15, and then the droplets (the liquid layer 25L) disposed on the intermediate layer 23D with the liquid repellent layer 24 interposed therebetween are fired so as to form the metal wiring film 19. This results in ridges and valleys (roughness) corresponding to the sizes of bonded silver fine particles occurring on the surface of the intermediate layer 23D. The liquid repellent layer 24 is, thus, unevenly formed so as to cover the surface in plane view, whereby the silver particles protrude in spots of the liquid repellent layer 24. Accordingly, in the case where the silver fine particles of the metal wiring film 19 are disposed on the intermediate layer 23D with the liquid repellent layer 24 sandwiched therebetween, the silver fine particles, which protrude in spots of the liquid repellent layer 24, of the intermediate layer 23D and the silver fine particles of the metal wiring film 19 are made contact with each other. As a result, physical and electrical connections between the intermediate layer 23D and the metal wiring film 19 are secured.

(2) In addition, the intermediate layer 23D and the metal wiring film 19 are made of the same metal, i.e., the silver fine particles. The silver fine particles are strongly bonded by the coagulation, and a stronger fusing force is easily obtained as compared with the junction or bonding between metals of different kinds. As a result, the intermediate layer 23D and the metal wiring film 19 are firmly connected and the electrical connection between them is more stably achieved though the liquid repellent layer 24 is sandwiched therebetween.

(3) Since the surface of the second electrode pad 15 is covered with gold of the plated layer 21, the surface of the second pad 15 is hardly oxidized. The conduction between the intermediate layer 23D formed on the surface and the main body 20 of the second electrode pad 15 is, thus, appropriately secured. Incidentally, if the intermediate layer 23D is formed by the inkjet method and an oxide film is formed on the second electrode pad 15, it is preferable that the droplets (the liquid layer 23L) of the conductive ink be disposed after removing the oxide film. However, no oxide film is formed. Thus, the intermediate layer 23D is easily formed by the inkjet method.

(4) Further, the electrical coupling between the intermediate layer 23D and the second electrode pad 15 with the plated layer 21 of gold interposed therebetween is appropriately secured since silver is bonded with gold stronger than aluminum.

(5) In the semiconductor device 10, the liquid repellent layer 24 is formed on an area excluding the intermediate layer 23D as a single molecule film showing desired liquid repellency. The liquid repellent layer 24 is disposed on the intermediate layer 23D having ridges and valleys as single molecule since it is the single molecule film. As a result, the single molecule is unevenly disposed and the silver fine particles protrude in spots of the liquid repellent layer 24. Accordingly, the silver fine particles of the intermediate layer 23D and the silver fine particles of the metal wiring film 19 are appropriately made contact with each other, while the single molecule film is sandwiched between the intermediate layer 23D and the metal wiring film 19, and thereafter they are bonded with a strong fusing force by being dried and fired. As a result, the stability of the electrical coupling between the second electrode pad 15 and the metal wiring film 19 is further improved.

(6) Since high liquid repellency with respect to the dispersion medium is given to the liquid repellent material, it is suppressed that the droplets (the liquid layer 25L) disposed by the inkjet method wet and spread. As a result, the inkjet method allows fine wiring patterns to be drawn to the semiconductor device 10.

The above embodiment may be changed as follows.

In the embodiment, the second electrode pad 15 serving as an electrode for connecting the semiconductor chip 14 to an external circuit is the electrode coupled to the metal wiring film 19 with the intermediate layer 23D interposed therebetween. The electrode pad is not limited to this. The electrode pad may be an electrode that is provided to the semiconductor device and has a pad-like shape. For example, an electrode pad formed on a substrate such as a mounting substrate may be employed. Specifically, the electrode coupled to the metal wiring film 19 with the intermediate layer 23D interposed therebetween may be the first electrode pad 13. Accordingly, any wiring line connected to a gold plated electrode pad of a semiconductor device can increase the degree of application freedom to the semiconductor device by using such wiring line forming method.

While the plated layer 21 is formed by a gold plating in the embodiment, metal to form the plated layer is not limited to gold but one may be used that secures the electrical connection to the intermediate layer formed by the inkjet method and is appropriately bonded to the silver fine particles. For example, metal hardly oxidized or metal having conductivity after being oxidized may be used to form the plated layer 21. Examples of metal hardly oxidized include noble metal such as gold, silver, and platinum. As for the metal having conductivity after being oxidized, rhodium is exemplified. As a result, the degree of selection freedom of plated layer is improved.

While gold is plated to the second electrode pad 15 by the nonelectrolytic plating or the electrolytic plating in the embodiment, the method is not limited to this. Gold may be plated to the second electrode pad by the inkjet method, for example. In the case of using the inkjet method, droplets of conductive fine particles including gold may be disposed in inert gas to the second electrode pad from which oxide films and the like have been removed, for example. As a result, the degree of forming method freedom of wiring line can be increased.

In the embodiment, the second electrode pad 15 has the plated layer 21 on the top surface thereof. The plated layer, however, may not be provided in a case where the electrical connection between the electrode pad and the wiring line formed on the top surface thereof by the inkjet method is appropriately secured; the main body of the electrode pad is formed by the metal hardly oxidized or the metal having conductivity after being oxidized.

In the embodiment, the main body 20 of the second electrode pad 15 is made of aluminum. The material is not limited to this. Another metal such as copper may be used to form the main body 20 as long as it functions as the electrode pad. As a result, the degree of selection freedom of a semiconductor device to which the wiring line forming method is applied.

If gold is plated on aluminum, it is known that gold is appropriately plated on a palladium layer formed on aluminum. The palladium layer may be formed on aluminum, and thereafter gold may be plated on the palladium layer.

In the embodiment, the liquid repellent layer 24 is formed in a manner such that the coating agent including the liquid repellent material is spread entirely over an area including the insulation layer 16 and the plated layer 21 above the pad forming face 14a, for example, by a dispenser method. However, the forming method is not limited to this. The liquid repellent layer 24 may be formed by other methods, such as a spin coater method, the inkjet method, and dipping, as long as the liquid repellent layer is entirely formed on the area above the pad forming face 14a. As a result, the degree of forming method freedom of liquid repellent layer is increased, and the method for forming a semiconductor device can be used for various purposes.

In the embodiment, the liquid repellent layer 24 is formed from the droplets, i.e., a liquid phase. However, the phase is not limited to this. The liquid repellent layer may be formed from a gaseous phase.

The liquid repellent layer may be formed by plasma irradiation at normal pressure. Various kinds of gases can be selected for this plasma treatment taking the surface material of the substrate into consideration. For example, fluorocarbon gases such as tetrafluoromethane, perfluorohexane, and perfluorodecane can be used as a treatment gas. In this case, a liquid repellent fluoride polymerized film can be formed as the liquid repellent layer.

The liquid repellent layer may be formed by bonding a film having desired liquid repellency, such as a polyimide film processed with tetrafluoroethylene, on the area above the pad forming face 14a.

In the embodiment, the liquid repellent layer 24 is formed entirely over the area including the insulation layer 16 and the plated layer 21 above the pad forming face 14a. However, the forming area is not limited to this. The liquid repellent layer 24 may be formed only on a necessary area above the pad forming face 14a. As a result, the degree of freedom of embodiment on a method for forming a liquid repellent layer.

In the embodiment, the silver nano paste constituting the liquid layers 23L and 25L is fired at 180° C. to 230° C. for 1 hour so as to form the intermediate layer 23D and the wiring layer 25D made of the silver fine particles. However, the firing conditions are not limited to these. The time and temperature for firing the silver nano paste may be arbitrarily changed based on the conditions such as particle diameters of the silver fine particles, the dispersant, and the dispersion medium that are used in the silver nano paste as long as the silver fine particles are bonded with a predetermined fusing force and fixed.

In the embodiment, the intermediate layer 23D and the metal wiring film 19 are formed by the metal fine particles of silver as a combination of the same kind of metal. However, the combination is not limited to this. A combination of different kinds of metals may be employed. For example, the intermediate layer 23D is formed by the metal fine particles of silver while the metal wiring film 19 is formed by the metal fine particles of cupper. In addition, a combination of the same alloy and a combination of different kinds of alloys may also be employed. Even above structure, metal fine particles constituting the intermediate layer 23D and the metal wiring film 19 are coagulated and bonded by drying and firing the conductive ink. The second electrode pad 15 and the metal wiring film 19 are more firmly connected and the electrical connection thereof becomes more stable as compared with the structure in which the intermediate layer is not provided.

The entire disclosure of Japanese Patent Application Nos: 2008-292463, filed Nov. 14, 2008 and 2009-220797, filed Sep. 25, 2009 are expressly incorporated by reference herein.

What is claimed is:

1. A semiconductor device, comprising:
an electrode pad;
a wiring line electrically coupled to the electrode pad, the wiring line being formed by disposing and drying a droplet of a conductive ink in which metal fine particles are dispersed in a dispersion medium;
an intermediate layer of an bonded layer of the metal fine particles on a surface of the electrode pad; and
a liquid repellent layer that includes a liquid repellent material repelling the dispersion medium and is layered on the intermediate layer to cover the intermediate layer, wherein the wiring line is physically coupled to the electrode pad with the liquid repellent layer and the intermediate layer interposed between the wiring line and the electrode pad.

2. The semiconductor device according to claim 1, wherein the intermediate layer and the wiring line are made of metal of a same kind.

3. The semiconductor device according to claim 1, wherein the surface of the electrode pad is plated with gold; and the intermediate layer is formed on the surface plated with gold.

4. The semiconductor device according to claim 1, wherein the liquid repellent layer is a single molecule film of the liquid repellent material.

5. The semiconductor device according to claim 1, wherein the liquid repellent material is a fluorine material.

6. The semiconductor device according to claim 1, wherein the electrode pad is an electrode that is provided on an active face of a semiconductor component as a connecting terminal to an external circuit, and has a pad-like shape.

7. A method for manufacturing a semiconductor device in which a wiring line electrically coupling to an electrode pad of the semiconductor device is formed by disposing and drying a droplet of a conductive ink in which metal fine particles are dispersed in a dispersion medium, the method comprising:
forming, on a surface of the electrode pad, an intermediate layer of a bonded layer of the metal fine particles;
layering a liquid repellent layer including a liquid repellent material repelling the dispersion medium to cover the intermediate layer after forming the intermediate layer; and
forming the wiring line on the electrode pad with the liquid repellent layer and the intermediate layer that have been layered interposed between the wiring line and the electrode pad.

8. The method for manufacturing a semiconductor device according to claim 7, wherein the intermediate layer and the wiring line are made of metal of a same kind.

9. The method for manufacturing a semiconductor device according to claim 7, wherein the surface of the electrode pad is plated with gold; and the intermediate layer is formed on the surface plated with gold.

10. The method for manufacturing a semiconductor device according to claim 7, wherein the liquid repellent layer is a single molecule film of the liquid repellent material.

11. The method for manufacturing a semiconductor device according to claim 7, wherein the droplet of the conductive ink is disposed on the electrode pad and fired to form the intermediate layer.

12. The method for manufacturing a semiconductor device according to claim 7, wherein the liquid repellent material is a fluorine material.
